(19) United States
(12) Patent Application Publication
(10) Pub. No.: US 2012/0082176 A1
(43) Pub. Date: Apr. 5, 2012

(54) CONDUCTION COOLED PACKAGE LASER AND PACKAGING METHOD FOR FORMING THE SAME

(75) Inventors: Szutsun Simon OU, Taipei (TW); Po-Wen HSIAO, Taipei County (TW); Chia-Hung HSIEH, Taipei County (TW); Hui-Ping YANG, Taipei County (TW); Ying-Feng HSU, Taoyuan County (TW)

(73) Assignee: ARIMA LASERS CORP., Taoyuan County (TW)

(21) Appl. No.: 13/072,793

(22) Filed: Mar. 28, 2011

(30) Foreign Application Priority Data
Sep. 30, 2010 (TW) 099133315

(51) Int. Cl. H01S 3/04; H01L 33/48

(52) U.S. Cl. 372/36; 438/26; 257/E33.056

(57) ABSTRACT

A packaging method for forming a conduction cooled package (CCP) laser is provided and includes soldering a semiconductor laser device on the first heat spreader; and then bonding the first heat spreader on the second spreader via an Al/Ni nano-laminated foil. Moreover, a CCP laser is also provided herein.

### RELATED APPLICATIONS

This application claims priority to Taiwan Application Serial Number 99133315, filed Sep. 30, 2010, which is herein incorporated by reference.

### BACKGROUND

1. Field of Invention

The present invention relates to a laser device and a method for packaging the laser device. More particularly, the present invention relates to a conduction cooled package (CCP) laser and a packaging method for forming the same.

2. Description of Related Art

Since having a built-in resonant cavity, a semiconductor laser (diode) has the advantages of small size and high plug conversion efficiency. Moreover, with a solid-state gain medium, the semiconductor laser (diode) also has the advantage of long operation life. Thus, the semiconductor laser (diode) has been widely applied in various industries such as machine tooling, welding, scribing, printing, medicine, and recently, it also has been used in laser TV, laser cinema for high definition 3D display.

However, just like many devices which unavoidably generate by-product heat during operation, the semiconductor laser diode also generates a lot of heat during high power operation even with a high electro-optic conversion rate. If not being removed from the semiconductor laser (diode) immediately and properly, the heat will accumulate therein and ultimately increase the junction temperature thereof and cause the failure of the semiconductor laser (diode). Thus, the heat dissipation becomes a main factor Affecting the light-emitting stability of the semiconductor laser. In a conventional packaging method for forming a CCP laser, a metal (solder) material such as Indium, AuSn, Sn or AgSn has been used to bond (solder) the semiconductor laser with a high thermally conductive element such as a copper block as the heat sink, thereby providing a path for transferring the heat from the semiconductor laser to the heat sink and then dissipating the heat through the heat sink (copper block) with a large surface area, thus reducing the junction temperature of the semiconductor laser (diode).

However, since the thermal expansion coefficients of the semiconductor laser (diode) and the heat sink are different, stress or strain will be generated therebetween when the temperature of the CCP laser rises. Such self-generated stress or strain changes the electronic and optical characteristics of the semiconductor laser (diode) and thus causes the failure of the semiconductor laser (diode) or inherently shortens the operation life the semiconductor laser (diode).

Moreover, if a semiconductor laser (bar) with a large area such as 1-cm wide and 0.1 cm long is bonded, the aforementioned stress can cause mechanical problems. Both end of the semiconductor laser (bar) will not be flatly attached to the heat sink, and will bow upwards similar to a smile pattern, which is referred to as a “smile effect”. Since the soldering process usually requires a long period high temperature process for melting the metal (solder) material, and thus the stress will be unavoidable generated within the semiconductor laser (diode). In addition, the brittle rupture of the semiconductor material may also occur due to the high temperature environment in the process.

Therefore, it is an important issue with regard to how to provide a new packaging method which can be performed at low temperature with less energy for preventing the stress from being generated.

### SUMMARY

Hence, an objective of the present invention is to provide a packaging method for forming a CCP laser, thereby reducing the high heat influence on the characteristics of the semiconductor laser during fabrication, and reducing the occurrence of the brittle rupture of the semiconductor laser.

Another objective of the present invention is to provide a CCP laser of which the characteristics will not be susceptible to the high heat during fabrication and the brittle rupture will not easily occur.

An aspect of the preset invention is to provide a packaging method for forming a CCP laser. The packaging method includes the following steps. At first, a semiconductor laser device is provided. Then, the semiconductor laser device is soldered on a first heat spreader. Thereafter, the first heat spreader is bonded to a second heat spreader via an Al/Ni nano-laminated foil.

According to one embodiment of the present invention, in the step of soldering the semiconductor laser device on the first heat spreader, the semiconductor laser device is soldered on the first heat spreader via an AuSn solder.

According to one embodiment of the present invention, in the step of bonding the first heat spreader to the second heat spreader, a soldering material layer is formed between the first heat spreader and the Al/Ni nano-laminated foil or between the second heat spreader and the Al/Ni nano-laminated foil.

According to one embodiment of the invention, in the step of bonding the first heat spreader to the second heat spreader, energy is applied on a side of the Al/Ni nano-laminated foil.

Another aspect of the preset invention is to provide a CCP laser. The CCP laser includes a first heat spreader, a second heat spreader, an Al/Ni nano-laminated foil and a semiconductor laser device.

The Al/Ni nano-laminated foil is disposed between the first heat spreader and the second heat spreader. The semiconductor laser device is soldered on the first spreader.

According to one embodiment of the present invention, the CCP laser further includes a soldering material layer formed between the first heat spreader and the Al/Ni nano-laminated foil or between the second heat spreader and the Al/Ni nano-laminated foil

According one embodiment of the invention, the semiconductor laser device is soldered on the first heat spreader via an AuSn solder.

In the embodiments of the present invention, the Al/Ni nano-laminated foil is arranged between the first heat spreader and the second heat spreader for preventing the semiconductor laser device from being affected by the heat generated in the fabrication process by using the characteristic of the Al/Ni nano-laminated foil. Thus, the characteristics of the semiconductor laser device can be prevented from being affected by heat and the fabrication process of the present invention is brief and can be performed easily.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a process flow chart of a packaging method according to one embodiment of the present invention;

FIG. 2A illustrates a schematic side view of a CCP laser according to one embodiment of the present invention;

FIG. 2B illustrates an enlarged view of the portion A shown in FIG. 2A;

FIG. 3 is a diagram showing the relationships of emission output power vs. current for the CCP lasers with/without the Al/Ni nano-laminated foil.

FIG. 4A and FIG. 4B are diagrams showing respective flatness measurements of the semiconductor laser arrays with/without the Al/Ni nano-laminated foil.

### DETAILED DESCRIPTION

Reference will be made in detail to the present embodiments of the invention, examples of which are illustrated in the accompanying drawings. Wherever possible, the same reference numbers are used in the drawings and the description to refer to the same or like parts.

Embodiments of the present invention is featured in using the characteristics of an Al/Ni nano-laminated foil arranged in a CCP laser to prevent the laser output characteristic from being affected in the packaging process for forming the CCP laser.

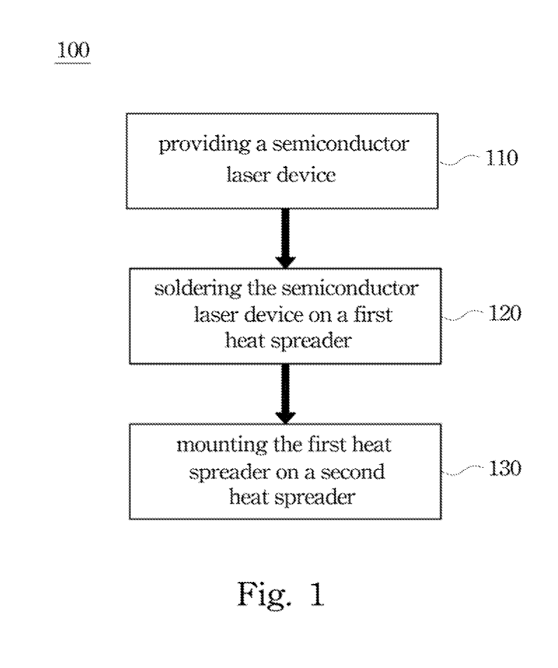

Referring to FIG. 1, FIG. 1 illustrates a process flow chart of a packaging method according to one embodiment of the present invention. At first, in step 110, a semiconductor laser device is provided. Then, in step 120, the semiconductor laser device is soldered on the first heat spreader. Thereafter, in step 130, the first heat spreader is bonded and fixed to the second heat spreader via an Al/Ni nano-laminated foil.

In step 120 an AuSn solder may be used to solder the semiconductor laser on the first heat spreader.

In step 130, the Al/Ni nano-laminated foil is made from a plurality of nanostructure materials. For example, the Al/Ni nano-laminated foil is composed of hundreds of Al and Ni nanostructure thin films laminated. This kind of nanostructure can induce a phenomenon of self-propagating exothermic reaction. With a small amount of thermal energy or a small electric impulse applied initially, the Al/Ni nano-laminated foil can generate high heat to fuse solder material in a very short time. Therefore, the heat spreaders can be bounded together without impacting the characteristics of the semiconductor laser device in the package process.

Further, the step of bonding the first heat spreader to the second heater spreader via the Al/Ni nano-laminated foil further includes forming a soldering material layer between the first heat spreader and the Al/Ni nano-laminated foil, and forming another soldering material layer between the second heat spreader and the Al/Ni nano-laminated foil. In other words, the soldering material layers are arranged between the first heat spreader and the Al/Ni nano-laminated foil, and between the second heat spreader and the Al/Ni nano-laminated foil respectively.

As to the method for bonding and fixing the first heat spreader to the second heater spreader, energy can be applied on a side of the Al/Ni nano-laminated foil for using the self-propagating exothermic reactions of the Al/Ni nano-laminated foil to fuse the solder in a short time for bonding and fixing the first heat spreader to the second heat spreader.

In this embodiment, an electric impulse is applied on the Al/Ni nano-laminated foil to fuse the solder by point discharge. However, the way for applying the initial energy applied on the Al/Ni nano-laminated foil is not limited thereto. A thermal energy or optical energy also can be applied on a side of the Al/Ni nano-laminated foil or other proper positions. Moreover, a compressive force also can be exerted on the Al/Ni nano-laminated foil to bond the first heat spreader and the second heat spreader together.

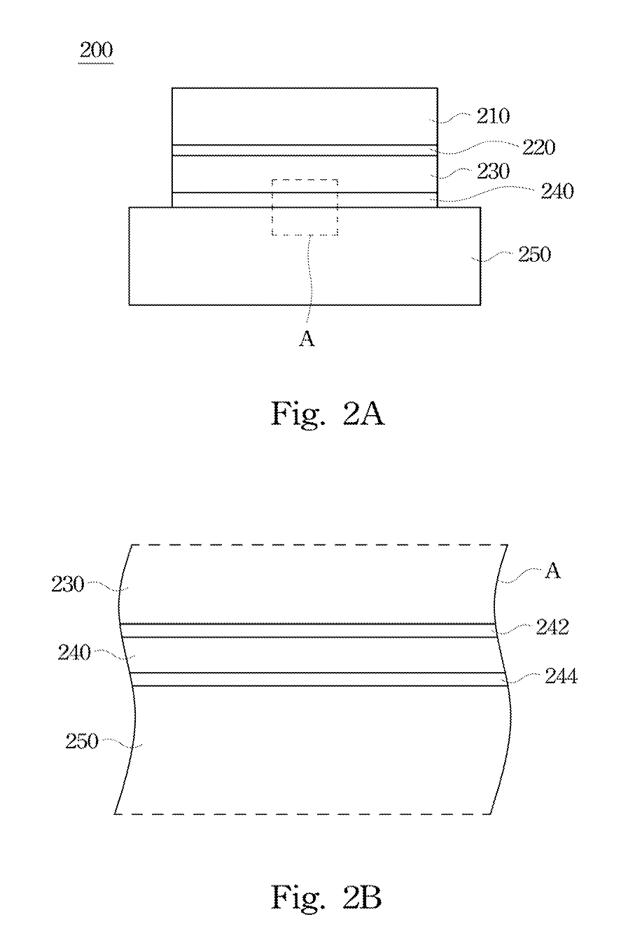

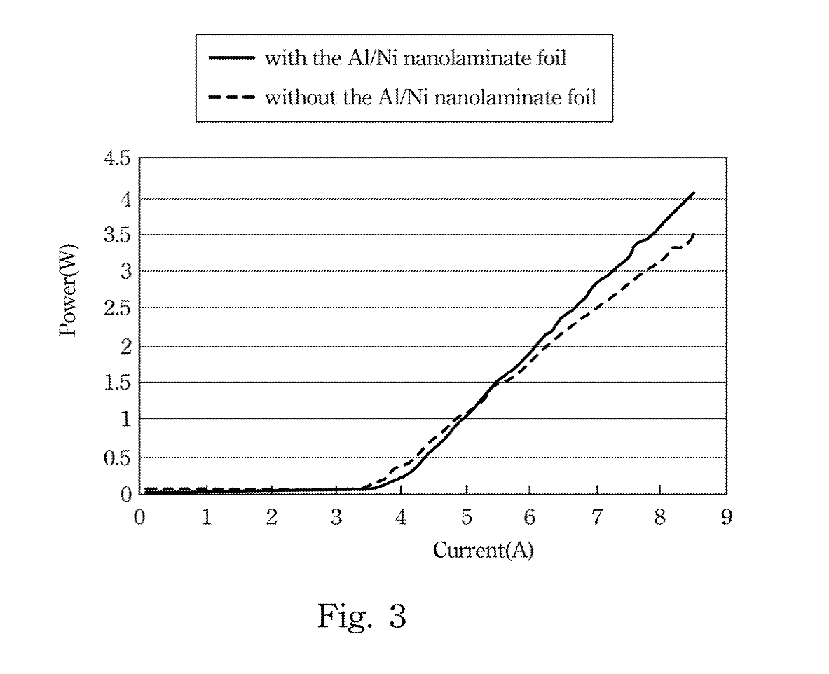

In order to describe the structure of the CCP laser, please refer to FIG. 2A in detail, which illustrates a schematic side view of a CCP laser structure according one embodiment of the present invention.

A CCP laser 200 includes a first heat spreader 230, a second heat spreader 250, an Al/Ni nano-laminated foil 240 and a semiconductor laser device 210. The Al/Ni nano-laminated foil 240 is arranged between the first heat spreader 230 and the second heat spreader 250. The semiconductor laser device 210 can be soldered on the first heat spreader 230 by an AnSn solder 220, wherein the AnSn solder eutectic point is suitable for the use in soldering semiconductor laser device 210 so that the reliability of the CCP laser 200 is increased.

Please refer to both FIG. 2A and FIG. 2B, wherein FIG. 2B illustrates an enlarged view of the portion A shown in FIG. 2A. The CCP laser 200 further includes soldering material layers 242 and 244, wherein the soldering material layer 242 is arranged between the first heat spreader 230 and the Al/Ni nano-laminated foil 240, and the soldering material layer 244 is arranged between the second heat spreader 250 and the Al/Ni nano-laminated foil 240.

In this embodiment, the soldering material layers 242 and 244 are made from tin solders. The first heat spreader 230 and the second heat spreader 250 are made from metals. Preferably, the first heat spreader 230 and the second heat spreader 250 are made from copper.

However, other materials also can be used for forming the aforementioned material layers and heat spreaders according to actual demands and designs. For example, the first heat spreader 230 and the second spreader 250 can be made from different metals. Moreover, the soldering material layers 242 and 244 can be made from different materials, such as Indium, AuSn, and Sn. By using the Indium solder having a high thermal conductivity and a desired expansion coefficient, good attachment and high thermal conductivity can be provided between of the heat spreaders made from proper materials. In other words, proper soldering materials can be selected to suit various materials forming the heat spreaders based on the adequacy of strain to increase the soldering strength, heat dissipating efficiency and the operation life of the CCP laser.

In the embodiment of the present invention, the semiconductor laser device 210 can be a laser bar, a vertical cavity surface emitting laser (VCSEL) or array, an edge emitting semiconductor laser or an in-plane surface emitting laser or array. After initial energy is applied on the side of the Al/Ni nano-laminated foil by point discharge during fabrication, the Al/Ni nano-laminated foil generates high temperature locally to fuse the soldering material layers 242 and 244 disposed on two opposite surfaces of the Al/Ni nano-laminated foil 24 in a very short time (about several milliseconds) due to the self-propagating exothermic reactions, thereby bonding the first heat spreader 230 and the second heat spreader 250 together.

According to the aforementioned features of the Al/Ni nano-laminated foil 24, the packaging process for forming the CCP laser can performed substantially in the room temperature environment. The reaction time is very short, and the reaction zone is limited in the proximity of the Al/Ni nano-laminated foil. Hence, the output characteristic of the semiconductor laser device is not affected in the packaging process, and the laser material can be kept intact easily. Moreover, this packaging process is straightforward and can be conducted easily.

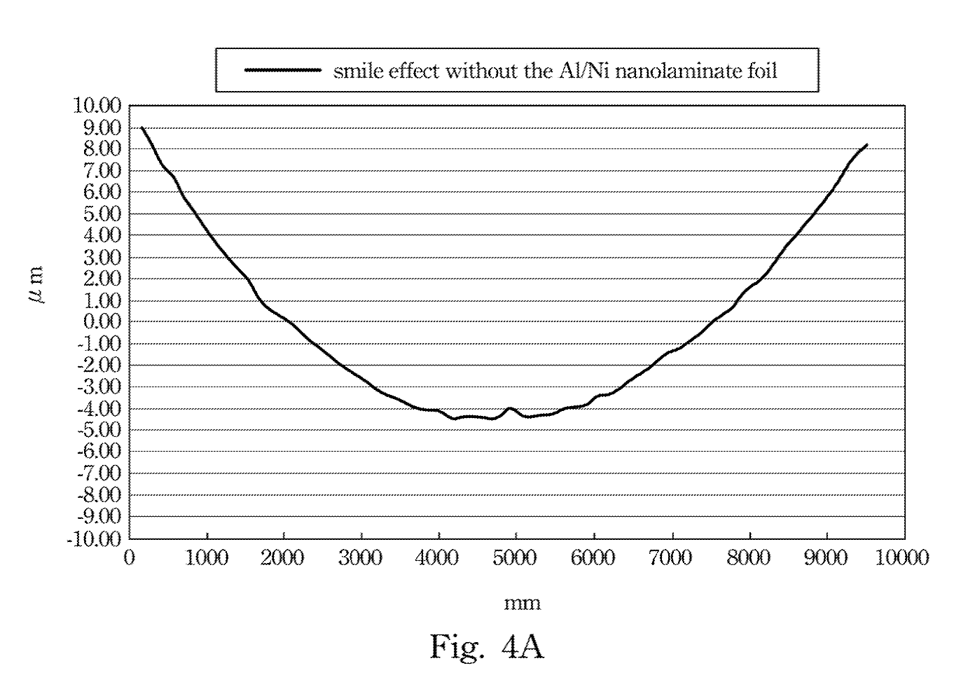

Referring to FIG. 3, FIG. 3 is a diagram showing the relationships of emission output power vs. current for the CCP lasers with/without the Al/Ni nano-laminated foil, wherein the solid line thereof represents the output power measurement of the semiconductor laser with the Al/Ni nano-laminated foil with respect to the current, and the dashed line thereof represents the output power measurement of the semiconductor laser without the Al/Ni nano-laminated foil with respect to the current. As shown in FIG. 3, the semiconductor laser with the Al/Ni nano-laminated foil has better output power with respect to most parts of the current range. Especially, in the high current range, the output power of the semiconductor laser with the Al/Ni nano-laminated foil is better than that without the Al/Ni nano-laminated foil.

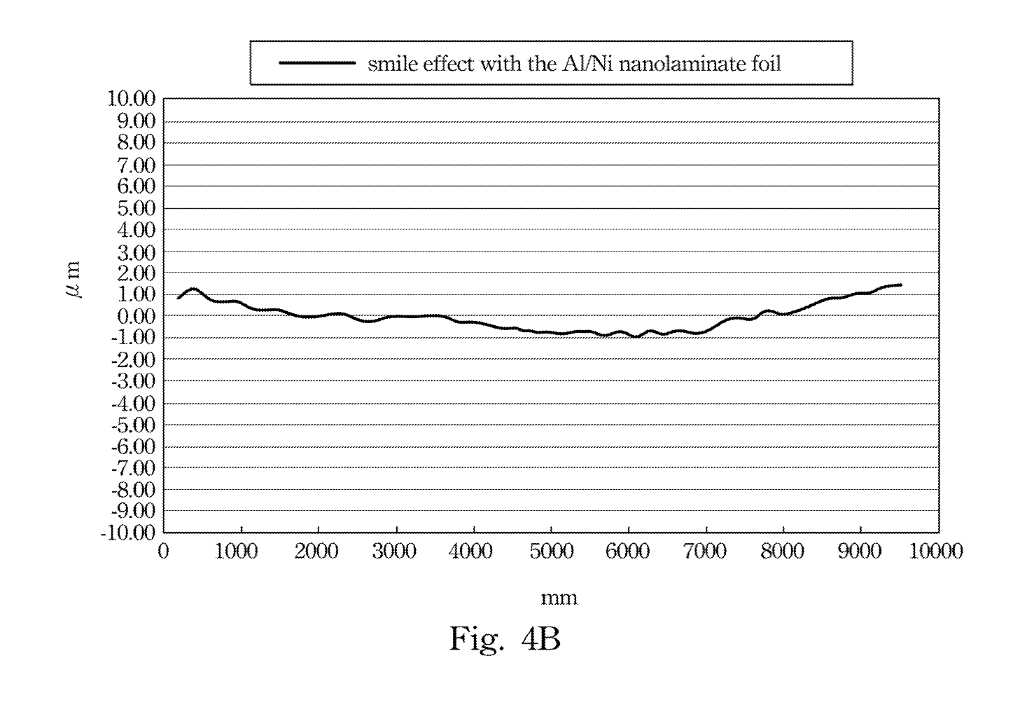

Referring to both FIG. 4A and FIG. 4B, FIG. 4A and FIG. 4B are diagrams showing respective flatness measurements of the semiconductor laser arrays with/without the Al/Ni nano-laminated foil. In FIG. 4A, no Al/Ni nano-laminated foil is used in the semiconductor laser array, and it can be known that the smile effect is very serious, and the laser beam cannot be emitted flatly. In FIG. 4B, the Al/Ni nano-laminated foil is used in the semiconductor laser array, and it can be known that the smile effect is greatly reduced due to the characteristic of the Al/Ni nano-laminated foil, and the semiconductor laser array is much flatter, and the voids among the respective interfaces are reduced, so that the heat dissipation is more uniform. Therefore, the output power and the optical efficiency of the semiconductor laser array with the Al/Ni nano-laminated foil can be increased, and the emission angle of each laser in the array can be kept the same and in flatness, so that the optical characteristic of the semiconductor laser array is promoted.

In comparison with the conventional packaging process which fuses the solder material such as Indium, AuSn, Sn, and AgSn to bond the heat sink and copper bulk together by heating and affects the characteristics of the semiconductor laser, the embodiments of this invention using the Al/Ni nano-laminated foil can limit the reaction zone within a very small area, and has very short reaction time, and thus the step of bounding two heat spreaders will not affect the characteristics of the semiconductor laser device during the whole packaging process.

In addition, proper solder and heat spreader can be selected and used to reduce the stress between the solder and the heat spreader, and to increase the heat dissipation, thus increasing the operation life and the stability of the CCP laser.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A packaging method of a conduction cooled package (CCP) laser, comprising:
providing a semiconductor laser device;
soldering the semiconductor laser device on a first heat spreader; and
bonding the first heat spreader to a second, heat spreader via an Al/Ni nano-laminated foil.

2. The method of claim 1, wherein the step of soldering the semiconductor laser device on the first heat spreader further comprises:
soldering the semiconductor laser device on the first heat spreader via an AuSn solder.

3. The method of claim 1, wherein the step of bonding the first heat spreader to the second heat spreader further comprises:
forming a soldering material layer between the first heat spreader and the Al/Ni nano-laminated foil or between the second heat spreader and the Al/Ni nano-laminated foil.

4. The method of claim 3, wherein the step of bonding the first heat spreader to the second heat spreader further comprises:
applying energy on a side of the Al/Ni nano-laminated foil.

5. The method of claim 3, wherein the step of bonding the first heat spreader to the second heat spreader further comprises:
applying electric energy, thermal energy, or optical energy on a side of the Al/Ni nano-laminated foil.

6. A conduction cooled package laser, comprising:
a first heat spreader;
a second heat spreader;
an Al/Ni nano-laminated foil disposed between the first heat spreader and the second heat spreader; and
a semiconductor laser device soldered on the first heat spreader.

7. The conduction cooled package laser of claim 6, further comprising:
a soldering material layer formed between the first heat spreader and the Al/Ni nano-laminated foil or between the second heat spreader and the Al/Ni nano-laminated foil.

8. The conduction cooled package laser of claim 7, wherein the soldering material layer is made from a tin solder, an Indium solder, or an AuSn solder.

9. The conduction cooled package laser of claim 6, wherein the second heat spreader is made from copper.

10. The conduction cooled package laser of claim 6, wherein the semiconductor laser device is soldered on the first heat spreader via an AuSn solder.

11. The conduction cooled package laser of claim 6, further comprising:
an AuSn solder disposed between the semiconductor laser device and the first heat spreader.
